(19) United States
(12) Patent Application Publication
(10) Pub. No.: US 2026/0239699 A1
(43) Pub. Date: Aug. 13, 2026

(54) ETCH STOP LAYER FOR 3D MEMORY

(71) Applicant: Applied Materials, Inc., Santa Clara, CA (US)

(72) Inventors: Chang Seok Kang, Santa Clara, CA (US); Tomohiko Kitajima, San Jose, CA (US); Min Gyu Sung, Latham, NY (US); Devika S. Grant, Hollister, CA (US); Ruiying Hao, San Jose, CA (US); Jongbeom Seo, San Jose, CA (US); Hoi Sung Chung, Sunnyvale, CA (US); Raghuveer Satya Makala, Campbell, CA (US); Balasubramanian Pranatharthiharan, San Jose, CA (US)

(73) Assignee: Applied Materials, Inc., Santa Clara, CA (US)

(21) Appl. No.: 19/208,761

(22) Filed: May 15, 2025

Related U.S. Application Data
(60) Provisional application No. 63/757,889, filed on Feb. 13, 2025.

(51) Int. Cl. H10D 62/832; H10B 12/00

(52) U.S. Cl. CPC H10D 62/832; H10B 12/02; H10B 12/312

(57) ABSTRACT

Provided are memory devices and methods of manufacture that include an etch stop layer on the bottom of the memory stack. The etch stop layer on the bottom of the memory stack is advantageous for backside wafer thinning in hybrid bonded memory devices.

### CROSS-REFERENCE TO RELATED APPLICATION

This application claims priority to U.S. Provisional Application Ser. No. 63/757,889, filed Feb. 13, 2025, the entire disclosure of which is hereby incorporated by reference herein.

### TECHNICAL FIELD

Embodiments of the disclosure pertain to the field of semiconductor devices and semiconductor device manufacturing. More particularly, embodiments of the disclosure provide three-dimensional dynamic random-access memory (3D DRAM) stacks and methods for forming 3D DRAM devices.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

As demands for miniaturization have grown, a need has developed for improving semiconductor device component density. Stacked semiconductor devices, e.g., three-dimensional integrated circuits, have been developed to reduce the physical size and two-dimensional footprint of semiconductor devices. In a stacked semiconductor device, active circuits (e.g., logic, memory, processor circuits, etc.) are fabricated on different semiconductor wafers. Two or more semiconductor wafers or dies may be mounted together through conventional techniques to increase device component density.

Generally, improvement in integration density has come from reduction of minimum feature sizes, allowing for integration of more components into smaller form factors. These integration improvements have been primarily two-dimensional in nature, inasmuch as the region occupied by integrated components has generally been on the surface of semiconductor wafers. Although dramatic improvements in lithography have resulted in considerable improvements in 2D integrated circuit formation, there are physical limits to the density that may be achieved in two dimensions. One of these limits is the minimum size required to manufacture discrete components. When more devices are integrated in a chip, more complex designs are required. Three-dimensional integrated circuits have therefore been developed to address some of these limitations. In representative manufacturing processes, two or more wafers, each including an integrated circuit, are formed. The wafers are then bonded with corresponding device elements aligned.

Hybrid bonding, which is a solid-state joining technology, and other advanced packaging technologies can be used to assemble the semiconductor devices so that they work as well as a single piece of silicon. Hybrid bonding provides a high density of vertical connections. For hybrid bonding 3D DRAM devices, backside wafer thinning is essential.

Accordingly, there is a need for 3D DRAM devices and methods of forming 3D DRAM devices to assemble into semiconductor devices using hybrid bonding.

### SUMMARY

One or more embodiments of the disclosure are directed to memory devices. In one or more embodiments, a memory device comprises: a memory stack on an etch stop layer on a substrate, the memory stack comprising a plurality of channel layers and a corresponding plurality of sacrificial layers alternatingly arranged in a plurality of stack pairs, the etch stop layer having an etch stop layer thickness and each of the plurality of sacrificial layers having a sacrificial layer thickness, the etch stop layer thickness greater than the sacrificial layer thickness.

Other embodiments of the disclosure are directed to methods of manufacturing a DRAM devices. In one or more embodiments, the method of manufacturing a DRAM device comprises: forming a memory stack on a sacrificial etch stop layer on a substrate, the memory stack comprising a plurality of channel layers and a corresponding plurality of sacrificial layers alternatingly arranged in a plurality of stacked pairs, the sacrificial etch stop layer having a first thickness and each of the plurality of sacrificial layers having a second thickness, the first thickness greater than the second thickness; replacing the sacrificial etch stop layer with an etch stop layer; and replacing each of the plurality of sacrificial layers with an oxide material.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope.

FIG. 1 illustrates a process flow diagram of a method of forming a 3D DRAM device according to one or more embodiments;

FIG. 2A illustrates a cross-sectional view of a substrate being processed according to the method of one or more embodiments;

FIG. 2B illustrates a top view of the substrate of FIG. 2A according to one or more embodiments;

FIG. 2C illustrates a top view of the substrate being processed according to the method of one or more embodiments;

FIG. 2D illustrates a top view of the substrate being processed according to the method of one or more embodiments;

FIG. 2E illustrates a top view of the substrate being processed according to the method of one or more embodiments;

FIG. 2F illustrates a cross-sectional view of a substrate being processed according to the method of one or more embodiments;

FIG. 2G illustrates a cross-sectional view of a substrate being processed according to the method of one or more embodiments;

FIG. 2H illustrates a cross-sectional view of a substrate being processed according to the method of one or more embodiments;

FIG. 2I illustrates a cross-sectional view of a substrate being processed according to the method of one or more embodiments;

FIG. 2J illustrates a cross-sectional view of a substrate being processed according to the method of one or more embodiments;

FIG. 2K illustrates a cross-sectional view of a substrate being processed according to the method of one or more embodiments;

FIG. 2L illustrates a cross-sectional view of a substrate being processed according to the method of one or more embodiments;

FIGS. 3A-3HH illustrate cross-sectional views of a substrate according to one or more embodiments; and

FIG. 4 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great details to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used in this specification and the appended claims, the terms “precursor”, “reactant”, “reactive gas”, and the like are used interchangeably to refer to any gaseous species that can react with the substrate surface.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

As used herein, the term “epitaxy” refers to a type of crystal growth or material deposition in which new crystalline layers are formed with one or more well-defined orientations with respect to a crystalline seed layer. The deposited crystalline film is called an epitaxial layer.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

The manufacturing of a DRAM cell includes the fabrication of a transistor, a capacitor, and three contacts: one each to the bitline, the wordline, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive wordlines through the cell, the size of the cell capacitor, and the compatibility of array devices with nonarray devices.

Hybrid bonding, which is a solid-state joining technology, and other advanced packaging technologies can be used to assemble the semiconductor devices of one or more embodiments so that they work as well as a single piece of silicon. In one or more embodiments, hybrid bonding provides a high density of vertical connections. In one or more embodiments, hybrid bonding of 3D DRAM devices uses an etch stop layer for backside wafer thinning. One or more embodiments of the disclosure advantageously provide methods for forming 3D DRAM devices with memory stacks having an etch stop layer for backside thinning. The presence of the etch stop layer provides a cost effective and reliable wafer thinning process. Some embodiments advantageously provide memory stacks for 3D DRAM devices including a plurality of channel layers, e.g., silicon (Si) layers, and a corresponding plurality of sacrificial layers, e.g., silicon germanium (SiGe) layers, alternatingly or alternately arranged in a plurality of stacked pairs.

Although the disclosure will routinely identify specific 3D DRAM devices, and components thereof, it will be readily understood that the device and methods are equally applicable to other memory devices, orientations thereof, as processes for forming such devices. Accordingly, the technology should not be considered to be so limited as for use with these specific devices or methods alone.

In one or more embodiments, metal deposition and other processes can be carried out in an isolated environment (e.g., a cluster process tool). Accordingly, some embodiments of the disclosure provide integrated tool systems with related process modules to implement the methods.

The embodiments of the disclosure are described by way of the Figures, which illustrate devices (e.g., 3D DRAM) and processes for forming devices in accordance with one or more embodiments of the disclosure. The processes shown are merely illustrative possible uses for the disclosed processes, and the skilled artisan will recognize that the disclosed processes are not limited to the illustrated applications.

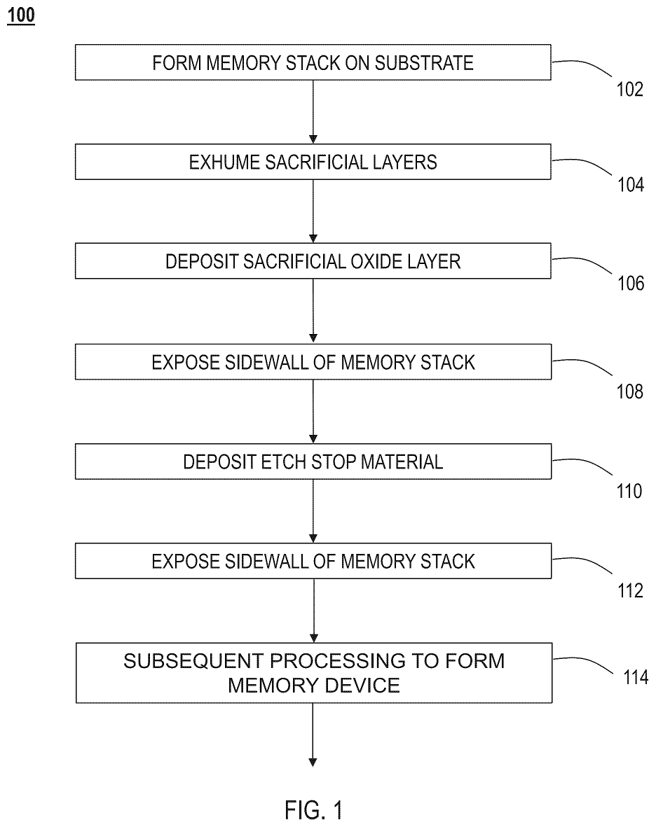

FIG. 1 illustrates a process flow diagram of a method 100 of forming a 3D DRAM device according to one or more embodiments. At operation 102 of the method 100, a memory stack is formed on a substrate. At operation 104, the sacrificial layers are exhumed or removed from the memory stack. At operation 106, a sacrificial oxide layer is deposited on the memory stack. At operation 108, the sidewall of the memory stack is exposed by removing a portion of the sacrificial oxide layer. At operation 110, an etch stop material is deposited on the memory stack. At operation 112, the side of the memory stack is exposed by removing a portion of the etch stop material from the sidewall of the memory stack. At operation 114, the device is processed according to standard processing to form the memory device.

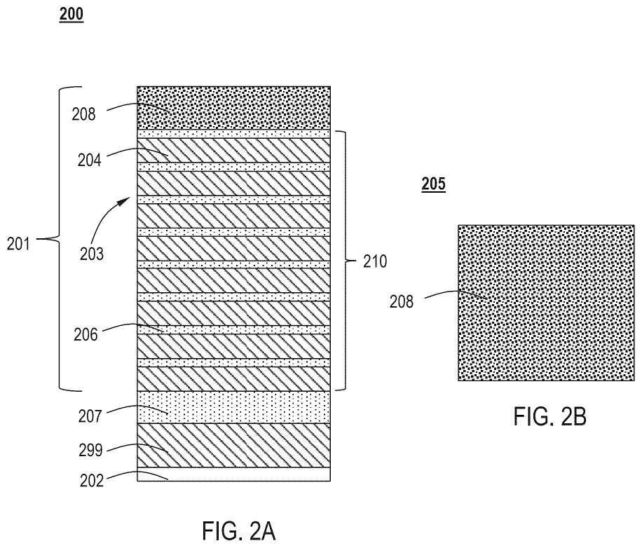

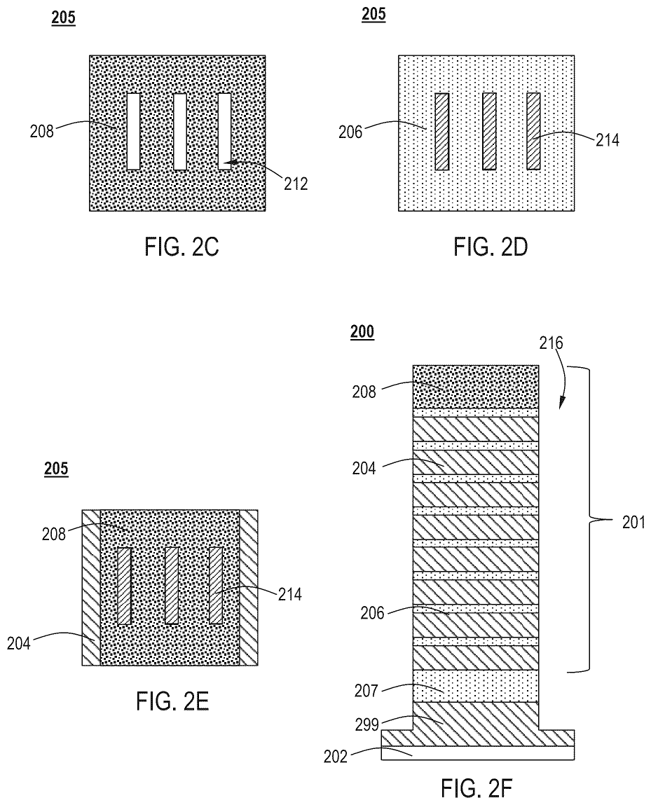

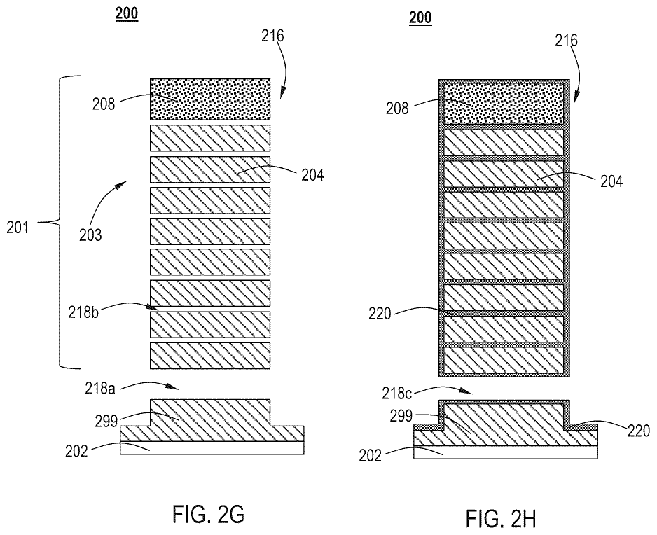

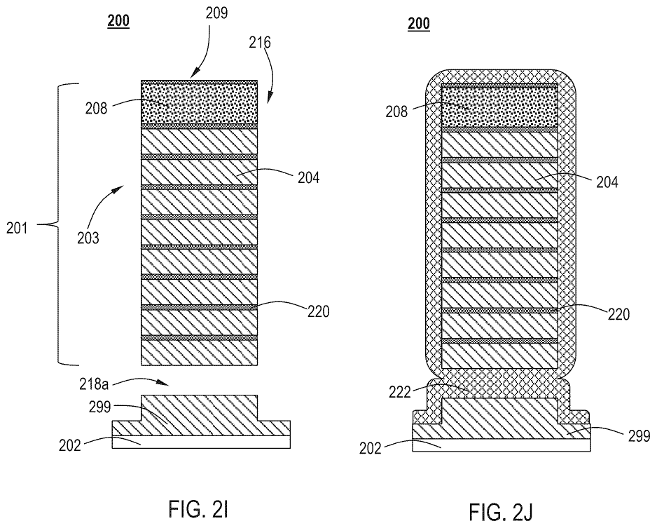

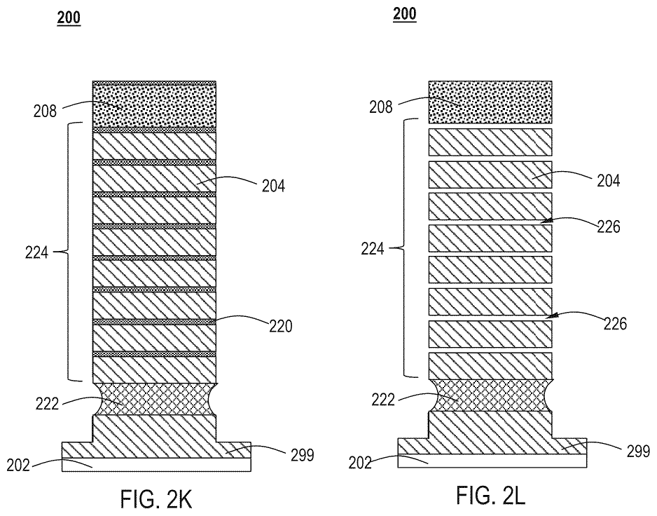

FIG. 2A illustrates a cross-sectional view of a substrate being processed according to the method of one or more embodiments, and FIG. 2B illustrates a top view of the substrate of FIG. 2A according to one or more embodiments. Referring to FIG. 1, and FIGS. 2A and 2B, one or more embodiments of the disclosure are directed to methods for forming 3D DRAM devices with memory stacks having an etch stop layer for backside thinning. Some embodiments advantageously provide memory stacks for 3D DRAM devices including a plurality of channel layers, e.g., silicon (Si) layers, and a corresponding plurality of sacrificial layers, e.g., silicon germanium (SiGe) layers, alternatingly arranged in a plurality of stacked pairs.

Still referring to FIG. 1 and FIG. 2A, at operation 102, a memory stack 201 is formed on a top surface of substrate 202. The substrate 202 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

In one or more embodiments, the memory stack 201 comprises a plurality of channel layers 204, e.g., silicon (Si) layers, and a corresponding plurality of sacrificial layers 206, e.g., silicon germanium (SiGe) layers, alternatingly arranged in a plurality of stacked pairs.

The skilled artisan will recognize that a channel layer 204 or silicon layer 299 is formed on the top surface of the substrate 202, or directly on the substrate 202. An etch stop layer 207 is formed on the surface of the silicon layer 299. A channel layer 204 is on the etch stop layer 207, followed by a sacrificial layer 206 formed on the surface of the channel layer 204.

In one or more embodiments, the silicon layer 299 has a thickness in a range of from greater than 0 nm to 100 nm, including in a range of from greater than 0 nm to 70 nm, including about 5 nm, about 10 nm, about 15 nm, about 20 nm, about 25 nm, about 30 nm, about 35 nm, about 40 nm, about 45 nm, about 50 nm, about 60 nm, about 65 nm, and about 70 nm. In one or more embodiments, the silicon layer 299 comprises, consists essentially of, or consists of epitaxial silicon. In some embodiments, the epitaxial silicon is completely or mostly single crystal.

In one or more embodiments, the plurality of channel layers 204 each have a thickness in a range of from greater than 0 nm to 100 nm, including in a range of from greater than 0 nm to 70 nm, including about 5 nm, about 10 nm, about 15 nm, about 20 nm, about 25 nm, about 30 nm, about 35 nm, about 40 nm, about 45 nm, about 50 nm, about 60 nm, about 65 nm, and about 70 nm. As used herein, the term “channel” refers to a layer of material that is an electrical conductor. In one or more embodiments, the channel layers 204 comprises one or more silicon, polysilicon, amorphous silicon, doped silicon, strained silicon, silicon on insulator (SOI), carbon doped silicon dioxides, SiGe, germanium, gallium arsenide, GaN, InP, carbon nanotube, and the like. In one or more embodiments, the channel layer 204 comprises, consists essentially of, or consists of epitaxial silicon. In some embodiments, the epitaxial silicon is completely or mostly single crystal.

In one or more embodiments, a sacrificial layer 206 is formed on, or directly on each of the plurality of channel layers 204. In one or more embodiments, each of the plurality of sacrificial layers 206 comprises a doped silicon germanium (SiGe) layer. The dopant may comprise any suitable dopant. In one or more embodiments, the dopant comprises carbon (C), and the sacrificial layer 206 comprises carbon-doped silicon germanium (SiGeC).

In one or more embodiments, the sacrificial layer 206 has a dopant concentration in the range of from 0 atomic % to 5 atomic %, including in a range of from greater than 0 atomic % to 2.5 atomic %, including in a range of from 0.1 atomic % to 2 atomic %, including in a range of from 0.1 atomic % to 1.5 atomic %, including in a range of from 0.1 atomic % to 1 atomic %. In some embodiments, the sacrificial layer 206 has a dopant concentration in the range of 0.01, 0.02, 0.03, 0.04, 0.05, 0.06, 0.07, 0.08, 0.09, or 0.1 atomic % to 1 atomic %. In some embodiments, the sacrificial layer 206 has a dopant concentration in the range of 0.01 atomic % to 0.1, 0.2, 0.3, 0.4, 0.5, 0.6, 0.7, 0.8, 0.9 or 1 atomic %. In some specific embodiments, the sacrificial layer 206 has a carbon (C) concentration in the range of 0.01 atomic % to 0.1, 0.2, 0.3, 0.4, 0.5, 0.6, 0.7, 0.8, 0.9 or 1 atomic %.

In one or more embodiments, the sacrificial layer 206 comprises a silicon germanium layer having a germanium concentration or germanium content in a range of from greater than 0 atomic % to 30 atomic % germanium, including in a range of from greater than 0 atomic % to 25 atomic % germanium, including in a range of from greater than 0 atomic % to 25 atomic % germanium, including in a range of from greater than 0 atomic % to 15 atomic % germanium, including in a range of from 5 atomic % to 15 atomic %, including in a range of from 10 atomic % to 30 atomic % germanium, and including in a range of from 10 atomic % to 25 atomic %. In one or more embodiments, the sacrificial layer 206 comprises a silicon germanium layer having a germanium content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, about 10 atomic %, about 11 atomic %, about 12 atomic %, about 13 atomic %, about 14 atomic %, about 15 atomic %, about 16 atomic %, about 17 atomic %, about 18 atomic %, about 19 atomic %, about 20 atomic %, about 21 atomic %, about 22 atomic %, about 23 atomic %, about 24 atomic %, about 25 atomic %, about 26 atomic %, about 27 atomic %, about 28 atomic %, about 29 atomic %, or about 30 atomic %.

While the memory stack 201, illustrated in FIG. 2A, has eight sets of alternating channel layers 204 and sacrificial layers 206, one of skill in the art recognizes that this is merely for illustrative purposes only. The memory stack 201 may have any number of alternating channel layers 204 and corresponding sacrificial layers 206. For example, in some embodiments, the memory stack 201 comprises 192 pairs of alternating channel layers 204 and corresponding sacrificial layers 206. In other embodiments, the memory stack 201 comprises greater than 50 pairs of alternating channel layers 204 and corresponding sacrificial layers 206, or greater than 200 pairs of alternating channel layers 204 and corresponding sacrificial layers 206, or greater than 300 pairs of alternating channel layers 204 and corresponding sacrificial layers 206. In one or more embodiments the alternating channel layers 204 and sacrificial layers 206, the sacrificial etch stop layer 207, and the silicon layer 299 are deposited by any suitable deposition process known to the skilled artisan including, but not limited to, atomic layer deposition (ALD), chemical vapor deposition (CVD), or physical vapor deposition (PVD).

In one or more embodiments, the sacrificial etch stop layer 207 is formed on the bottom of the memory stack 201 and on the silicon layer 299. The sacrificial etch stop layer 207 has a thickness that is greater than the thickness of the sacrificial layers 206. In some embodiments, the sacrificial etch stop layer 207 has a thickness in a range of from greater than 10 nm to 100 nm, or in a range of from greater than 10 nm to 60 nm, including 15 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, and 100 nm. In one or more embodiments, the thickness of the etch stop layer 207 is in a range of from 1 nm to about 20 nm smaller than about one half the size of the critical dimension of the memory hole of the DRAM device. Accordingly, in one or more embodiments, the thickness of the etch stop layer 207 is in a range of from greater than the thickness of the sacrificial layer 206 to half the critical dimension of the memory hole.

In one or more embodiments, the sacrificial etch stop layer 207 is formed on, or directly on the silicon layer 299. The sacrificial etch stop layer 207 may comprise any suitable material known to the skilled artisan. In one or more embodiments, the sacrificial etch stop layer 207 comprises silicon germanium (SiGe). In one or more embodiments, the etch stop layer 207 comprises a silicon germanium (SiGe) layer. The silicon germanium (SiGe) of the etch stop layer 207 may be doped or undoped. When present, the dopant may comprise any suitable dopant. In one or more embodiments, the dopant comprises carbon (C), and the sacrificial etch stop layer 207 comprises carbon-doped silicon germanium (SiGeC).

In one or more embodiments, the sacrificial etch stop layer 207 comprises a silicon germanium (SiGe) layer having a germanium (Ge) concentration or germanium (Ge) content in a range of from greater than 0 atomic % to 10 atomic % germanium, including in a range of from including in a range of from greater than 0 atomic % to 7 atomic %. In one or more embodiments, the sacrificial etch stop layer 207 comprises a silicon germanium layer having a germanium (Ge) content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, or about 10 atomic %.

In one or more embodiments, the concentration of germanium (Ge) in the etch stop layer 207 is different than the concentration of germanium (Ge) in the sacrificial layer(s) 206 of the memory stack 201. In some embodiments, the concentration of germanium (Ge) in the etch stop layer 207 is less than the concentration of germanium (Ge) in the sacrificial layer(s) 206 of the memory stack 201.

In one or more embodiments, a hard mask 208 is formed on a top surface of the memory stack 201. FIG. 2B illustrates a top view of the substrate of FIG. 2A according to one or more embodiments showing the hard mask 208. The hard mask 208 may comprise any suitable material known to the skilled artisan. In some embodiments the hard mask 208 comprises one or more of spin-on carbon, silicon dioxide, silicon carbide, titanium nitride, tantalum nitride, and the like.

FIGS. 2C-2D illustrate top views of the substrate of being processed according to one or more embodiments. As illustrated in FIG. 2C, an isolation slot 212 is patterned into the memory stack 201. In one or more embodiments, the isolation slot 212 is then filled with a deep trench isolation (DTI) material 214, as illustrated in FIG. 2D. The deep trench isolation (DTI) material 214 may comprise any suitable material known to the skilled artisan. In some embodiments, the deep trench isolation (DTI) material is selected from one or more of silicon dioxide, silicon nitride, polysilicon, and the like.

Referring to FIGS. 2E and 2F, in one or more embodiments, at least one feature 216 or opening or trench is etched into the memory stack 201. The at least one feature 216 may be formed by any suitable etching method known to the skilled artisan.

The aspect ratio of the at least one feature 216, e.g., memory hole, described in the disclosure is defined as the depth D of the feature divided by the width W. In one or more embodiments, the at least one feature 216, e.g., memory hole, has an aspect ratio (D:W) greater than or equal to about 20:1, greater than or equal to about 50:1, greater than or equal to about 100:1, or greater than or equal to about 200:1.

In one or more embodiments, at least one feature 216 extends a distance into the substrate 202 so that the sidewall surface and the bottom of the at least one feature 216 is formed within the substrate 202. The bottom of the at least one feature 216 can be formed at any point within the thickness of the substrate 202. In some embodiments, the at least one feature 216 extends a thickness into the substrate 202 in the range of from about 10% to about 90%, or in the range of from about 20% to about 80%, or in the range of from about 30% to about 70%, or in the range of from about 40% to about 60% of the thickness of the substrate 201. In some embodiments, the at least one feature 216 extends a distance into the substrate 202 by greater than or equal to 10%, 20%, 30%, 40%, 50%, 60%, 70%, or 80% of the thickness of the substrate 202.

Referring to FIG. 1, at operation 104, in one or more embodiments, the plurality of sacrificial layers 206 and the sacrificial etch stop layer 207 may be removed to form openings in the memory stack. With reference to FIG. 2G, in one or more embodiments, the sacrificial layers 206 and the etch stop layer 207 are removed through the at least one feature 216 to form lateral openings 218. In one or more embodiments, the lateral opening 218a formed by removal of the etch stop layer 207 has a thickness or height greater than the thickness or heigh of the lateral opening 218b formed by removal of the plurality of sacrificial layer(s) 206.

In some embodiments, the thickness of the lateral opening 218a formed by removal of the etch stop layer 207 is about half (1/2) the critical dimension (CD) of the at least one feature 216, and the thickness of the lateral opening 218b formed by removal of the plurality of sacrificial layer(s) 206 is less than the thickness of the lateral opening 218a formed by removal of the etch stop layer 207.

Referring to FIG. 1 and FIG. 2H, at operation 106, in one or more embodiments, a sacrificial oxide material 220, e.g., silicon oxide (SiOₓ), may be deposited on the memory stack 201 and in the openings 218b formed by removal of the sacrificial layers 206 and in the opening 218a formed by remove of the sacrificial etch stop layer 207. In one or more embodiments, the opening 218a formed by removal of the sacrificial etch stop layer 207 is not completely filled by the sacrificial oxide material 220, leaving a portion 218c open and unfilled.

With reference to FIG. 1 and FIG. 2I, at operation 108 in one or more embodiments, the sacrificial oxide material 220 may be removed from the sidewalls 203 of the memory device 201 and from the opening 218a formed by removal of the sacrificial etch stop layer 207.

Referring to FIG. 1 and FIG. 2J, at operation 110, in one or more embodiments, an etch stop material 222, e.g., silicon nitride (SiN), may then be deposited on the memory stack 201 and in the opening 218a formed by removal of the sacrificial etch stop layer 207. The etch stop material 222 fills the opening 218a formed by removal of the sacrificial etch stop layer 207 and forms on the sidewalls 203 and top 209 (i.e., on the hard mask 208) of the memory stack 201. The etch stop material 222 may be formed by any suitable deposition technique known to the skilled artisan, such as, but not limited to, ALD, CVD, PVD, MBE, MOCVD, spin-on, or other deposition techniques known to the skilled artisan. In some embodiments, the etch stop material 222 is deposited on the device 200 by ALD.

With reference to FIG. 1 and FIG. 2K, at operation 112, in one or more embodiments, the etch stop material 222 is removed from the sidewalls 203 and top 209 of the memory stack 201, exposing the sidewalls 203 and top 209 and forming a memory cell 224 on the etch stop material 222. The etch stop material 222 may be removed from the sidewalls 203 of the memory stack 201 by any suitable technique known to the skilled artisan. In one or more embodiments, the etch stop material 222 may be removed from the sidewalls using a conventional etching method such plasma dry etch or a wet etch. The dummy gate structure is removed by a selective etch process.

Referring to FIG. 2L, in one or more embodiments, the oxide material 220 is selectively exhumed or removed from the memory cell 224 to form lateral openings 226 between the plurality of channel layers 204. In one or more embodiments, the oxide material 220 is removed by one or more of wet etching or dry etching.

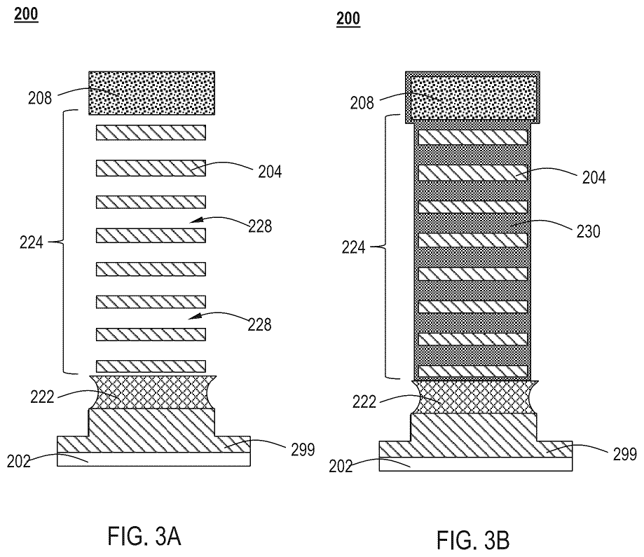

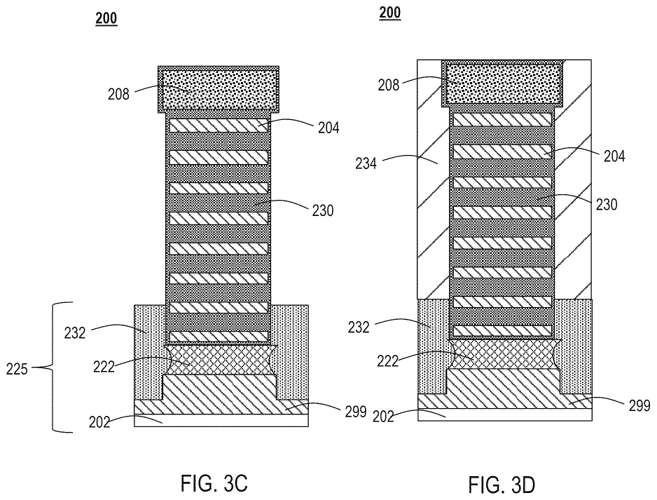

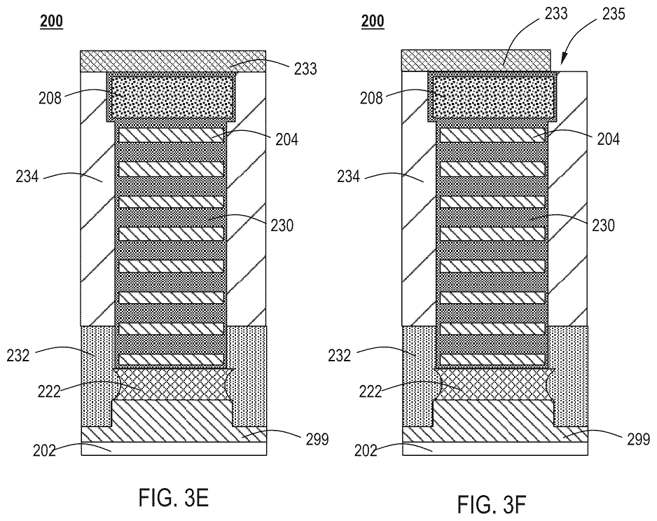

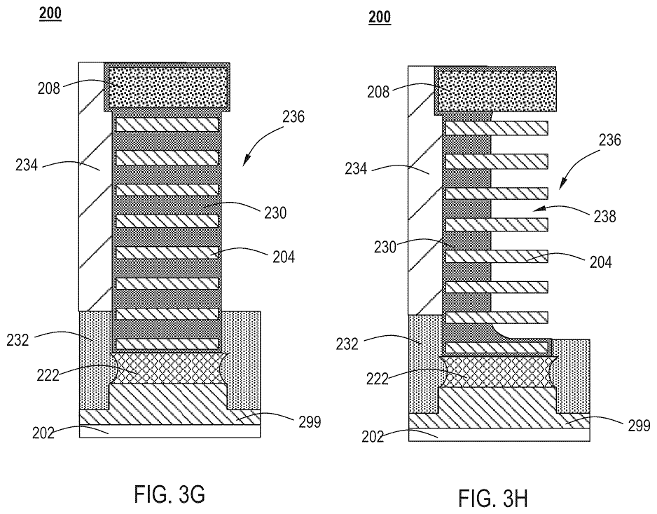

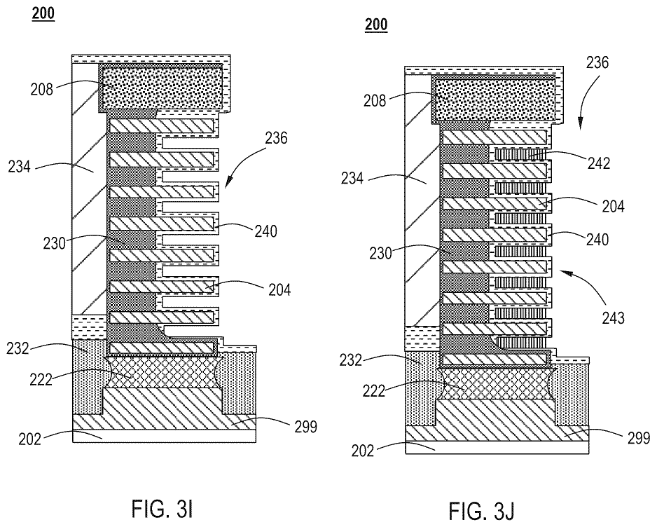

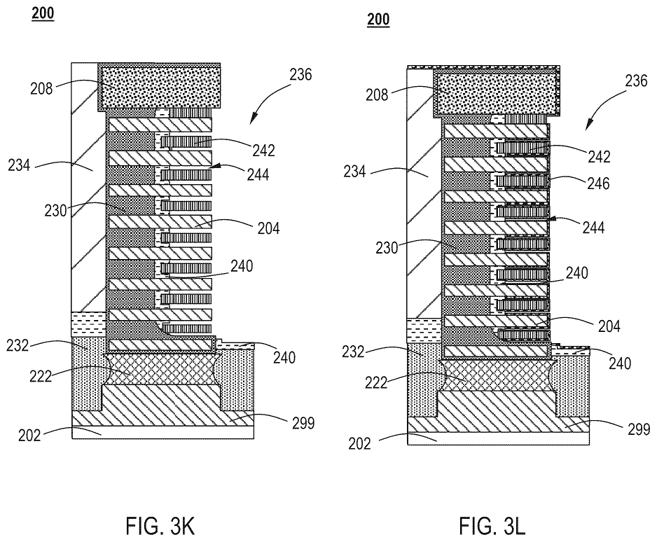

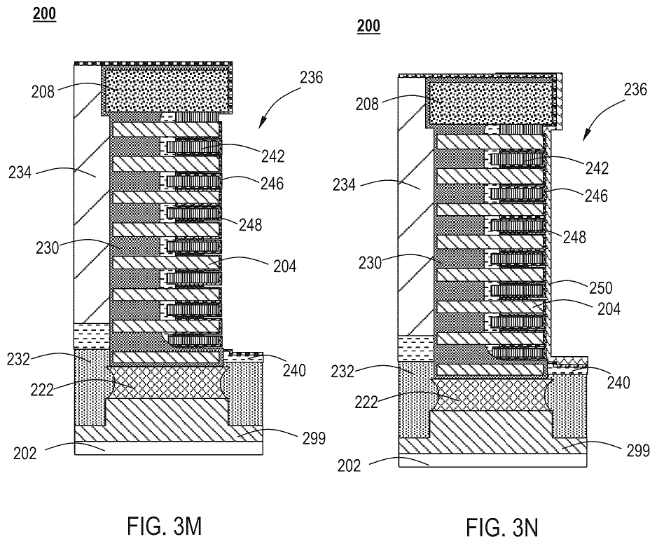

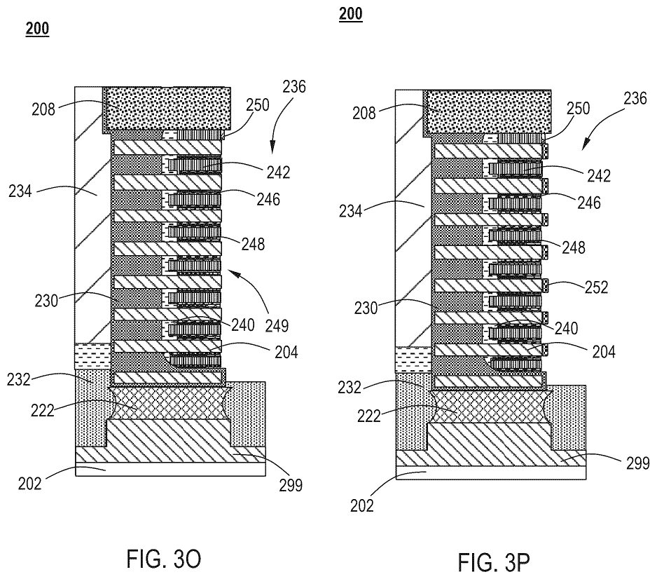

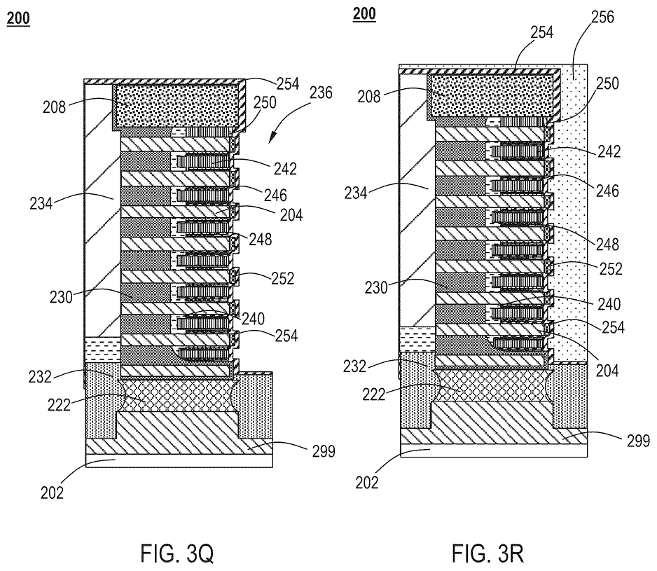

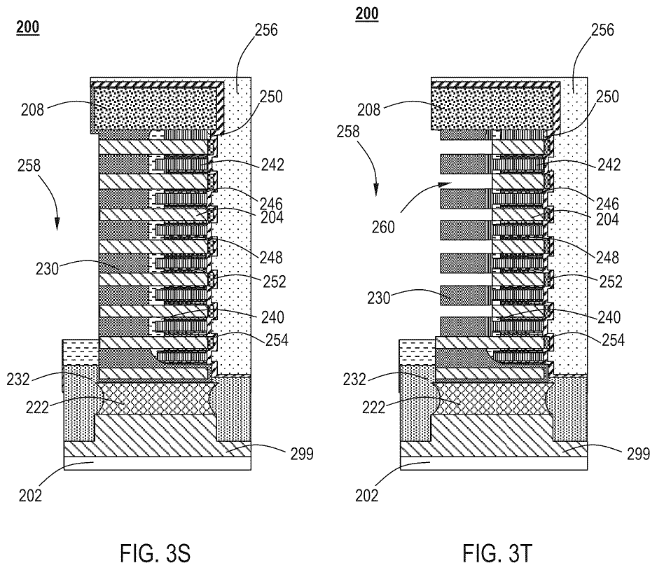

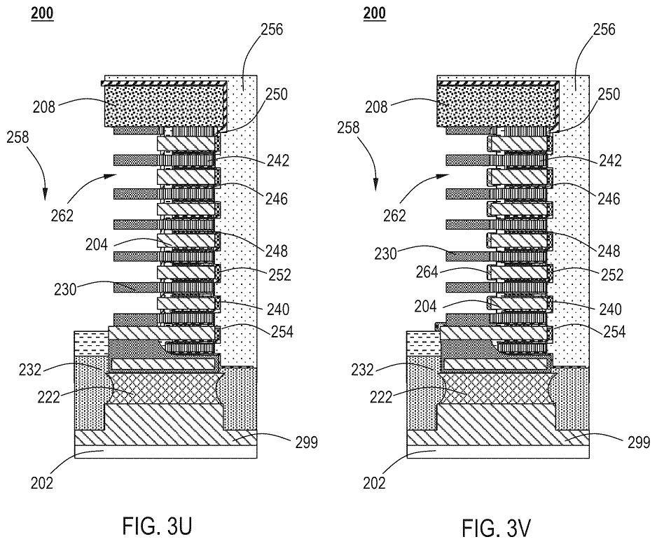

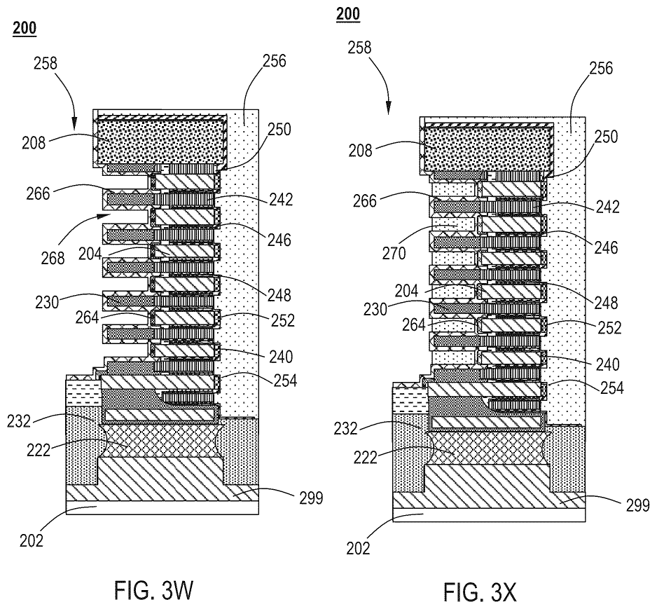

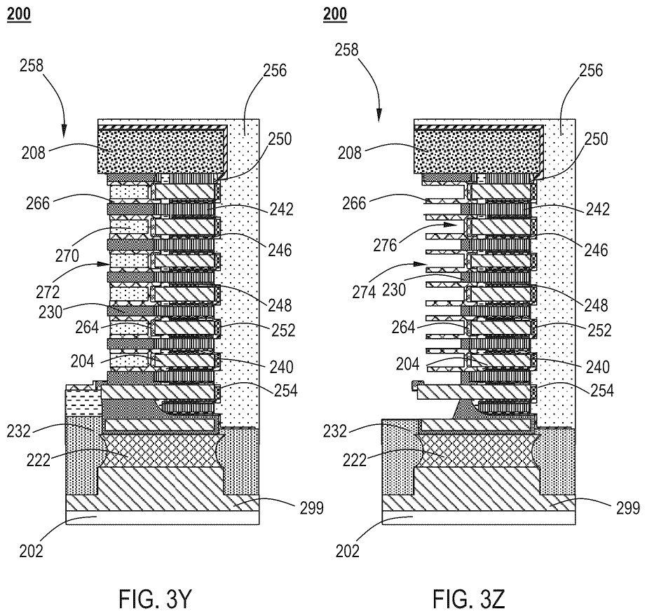

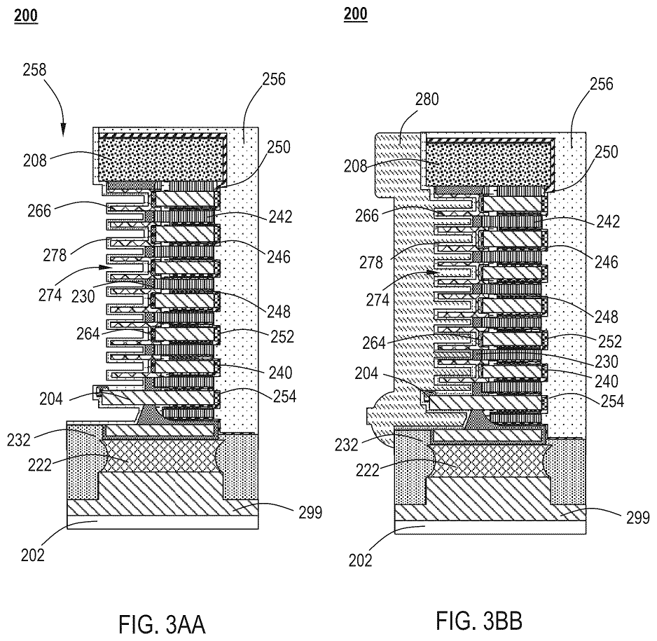

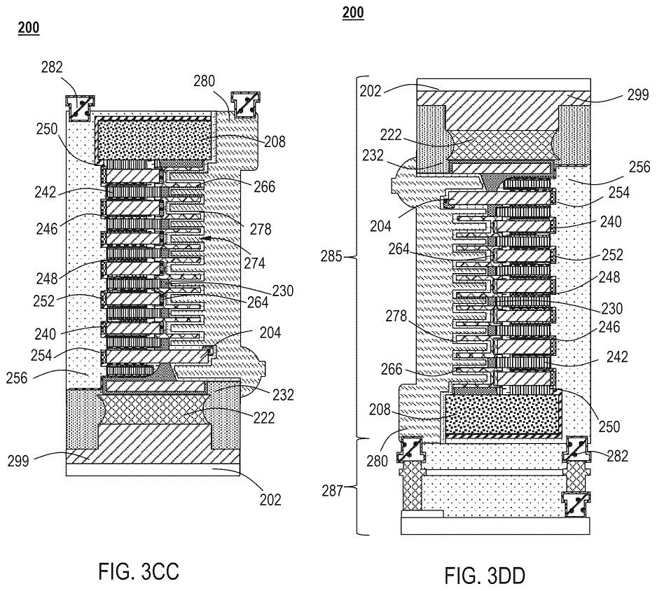

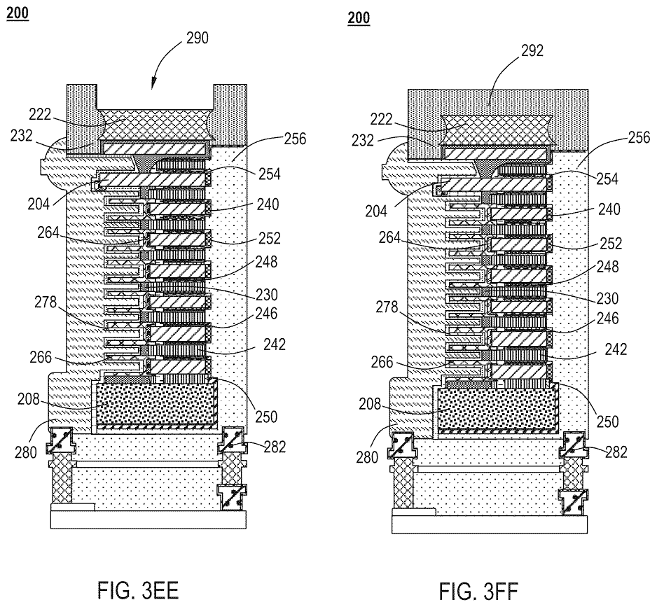

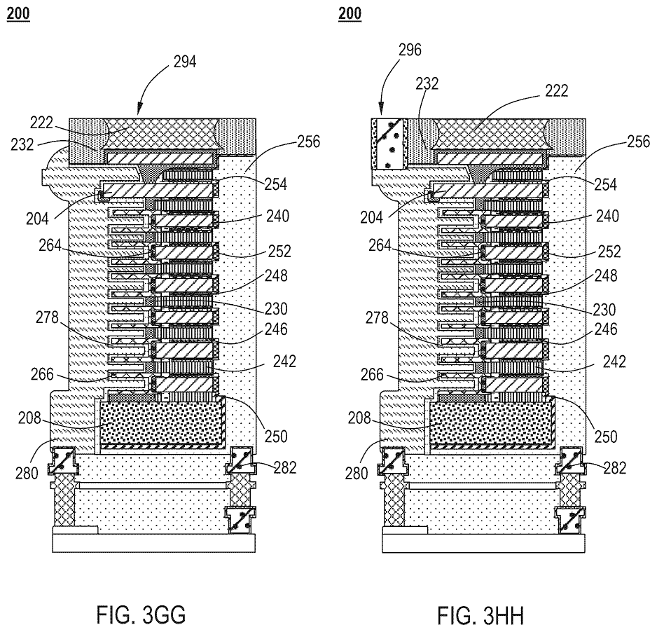

In one or more embodiments, formation of the DRAM device 200 proceeds according to standard processing, as illustrated in FIGS. 3A-3HH and at operation 114 of FIG. 1. With reference to FIG. 3A, the plurality of channel layers 204 are thinned or trimmed to increase the height of the opening 228 between adjacent channel layers 204. The plurality of channel layers 204 may be trimmed according to any suitable process known to the skilled artisan.

Referring to FIG. 3B, in one or more embodiments, the opening 228 is filled with an oxide material 230, e.g., silicon oxide (SiOₓ).

With reference to FIG. 3C, a second oxide material 232 is deposited on the substrate 202 and in contact with the etch stop material 222 on the bottom portion 225 of the device 200. As illustrated in FIG. 3D, a sacrificial layer 234 is formed on the second oxide material 232. The sacrificial layer 234 may comprise any suitable material. For example, in some embodiments, the sacrificial layer 234 may comprise a carbon-based material, such as, but not limited to, carbon, or carbon doped with one or more of boron, silicon, and nitrogen.

Referring to FIG. 3E, in one or more embodiments, a hard mask 233 is formed on a top surface of the device 200. The hard mask 233 may comprise any suitable material known to the skilled artisan. In some embodiments the hard mask 233 comprises one or more of spin-on carbon, silicon dioxide, silicon carbide, titanium nitride, tantalum nitride, and the like.

In one or more embodiments, as depicted in FIG. 3F, the hard mask 233 is opened to form an opening 235 that exposes the sacrificial material 234. The hard mask 233 may be opening using any suitable method known to the skilled artisan.

As illustrated in FIG. 3G, the sacrificial material 234 is removed from a portion of the device 200 to form a bit line trench 236. The sacrificial material 234 may be removed using any suitable removal process known to the skilled artisan.

With reference to FIG. 3H, the oxide material 230 is recessed through the bit line trench 236 to form a recess opening 238 between the plurality of channel layers 204. The recessing of the oxide material 230 may comprise any suitable recess process known to the skilled artisan.

Referring to FIG. 3I, a dielectric layer 240 is deposited on the device 200 and in the recess opening 238. The dielectric layer 240 may comprise any suitable dielectric material known to the skilled artisan. In one or more embodiments, the dielectric layer 240 comprises silicon nitride (SiN). In some embodiments, the dielectric layer 240 is a conformal layer. The dielectric layer 240 may be formed by any suitable deposition technique known to the skilled artisan, such as, but not limited to, ALD, CVD, PVD, MBE, MOCVD, spin-on, or other deposition techniques known to the skilled artisan. In some embodiments, the dielectric layer 240 is conformally deposited on the device 200 by ALD.

As illustrated in FIG. 3J, an oxide layer 242 is then deposited on the dielectric layer 240 to fill the recess opening 238. As recognized by one of skill in the art, when the oxide layer 242 is deposited, an overburden of oxide layer 242 may form, which may be removed using a technique such as chemical-mechanical planarization (CMP) to expose the sidewall 243 of the device in the bit line trench 236. The oxide layer 242 may be formed by any suitable deposition technique known to the skilled artisan, such as, but not limited to, ALD, CVD, PVD, MBE, MOCVD, spin-on, or other deposition techniques known to the skilled artisan. In some embodiments, the oxide layer 242 is deposited on the device 200 by ALD.

With reference to FIG. 3K, the dielectric layer 240 is recessed to form a recess opening 244 adjacent to the oxide layer 242 and the plurality of channel layers 204. The recessing of the dielectric layer 240 may comprise any suitable recess process known to the skilled artisan.

Referring to FIG. 3L, in one or more embodiments, a gate oxide layer 246 is deposited through the bit line trench 236 onto the plurality of channel layers 204 and the oxide layer 242. The gate oxide layer 246 may comprise any suitable material known to the skilled artisan. The gate oxide layer 246 can be deposited using one or more deposition techniques known to the skilled artisan. In one or more embodiments, the gate oxide layer 246 is deposited using one of any suitable deposition technique, such as, but not limited to, ALD, CVD, PVD, MBE, MOCVD, spin-on, or other deposition techniques known to the skilled artisan. The illustrated embodiment shows the gate oxide layer 246 as a conformal layer with a uniform shape. However, the skilled artisan will recognize that this is merely for illustrative purposes and that the gate oxide layer 246 can form in an isotropic manner so that the gate oxide layer 246 has a rounded appearance. In some embodiments, the gate oxide layer 246 is selectively deposited as a conformal layer on the surface of the plurality of channel layers 204 and the oxide layer 242. In one or more embodiments, the gate oxide layer 246 comprises silicon oxide (SiOₓ). While the term “silicon oxide” may be used to describe the gate oxide layer 246, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. The same is true for the other materials listed in this disclosure, e.g., silicon nitride, silicon oxynitride, tungsten oxide, zirconium oxide, aluminum oxide, hafnium oxide, and the like.

As illustrated in FIG. 3M, word line 248 is then formed in the opening 244. The word lines 248 may comprise one or more of a barrier layer and a word line metal, not illustrated. The barrier layer may comprise any suitable barrier layer known to the skilled artisan. In one or more embodiments, the barrier layer comprises one or more of titanium nitride (TiN), tantalum nitride (TaN), and the like. In one or more embodiments, the word line metal may comprise a bulk metal comprising one or more of copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the word line metal comprises tungsten (W). In other embodiments, the word line metal comprises ruthenium (Ru).

With reference to FIG. 3N, in one or more embodiments, a dielectric layer 250 is deposited on the device. The dielectric layer 250 may comprise any suitable material known to the skilled artisan. In one or more embodiments, the dielectric layer 250 comprises silicon nitride (SiN). In some embodiments, the dielectric layer 250 is a conformal layer. The dielectric layer 250 may be formed by any suitable deposition technique known to the skilled artisan, such as, but not limited to, ALD, CVD, PVD, MBE, MOCVD, spin-on, or other deposition techniques known to the skilled artisan. In some embodiments, the dielectric layer 250 is conformally deposited on the device 200 by ALD.

Referring to FIG. 3O, in one or more embodiments, the dielectric layer 250 and the gate oxide layer 242 are removed from the sidewall of the device 200 to expose a sidewall surface 249. The dielectric layer 250 and the gate oxide layer 242 may be removed using any suitable process known to the skilled artisan.

As illustrated in FIG. 3P, in one or more embodiments the bit line source drain is formed by deposition of a source/drain material 252 on the exposed sidewall surface 249 of the plurality of channel layers 204. The source/drain material 252 may comprise any suitable material known to the skilled artisan. In some embodiments, the source/drain material 252 may have more than one layer. In some embodiments, the source/drain material 252 comprises a layer of silicon with doped epi (e.g., Si, SiGe, and the like doped with one or more dopant), a second layer of silicide, which may contain nickel (Ni), titanium (Ti), aluminum (Al), and the like, and a third, or top, layer which may be a metal such as, but not limited to, cobalt, tungsten, ruthenium, aluminum, and the like.

With reference to FIG. 3Q, in one or more embodiments, the bit line material 254 is deposited on the device 200 and on the source/drain material 252. In one or more embodiments, the bit line material 254 may include an optional bit line liner (also referred to as a bit line barrier layer) and a bit line metal.

The optional bit line liner can be made of any suitable material deposited by any suitable technique known to the skilled artisan. In one or more embodiments, the bit line liner is deposited on the source/drain material 252. The bit line liner can be any suitable material including, but not limited to, titanium nitride (TiN) or tantalum nitride (TaN). In some embodiments, the optional bit line liner comprises or consists essentially of titanium nitride (TiN). As used in this manner, the term “consists essentially of” means that the composition of the film is greater than or equal to about 95%, 98%, 99% or 99.5% of the stated species. In some embodiments, the optional bit line liner comprises or consists essentially of tantalum nitride (TaN). In some embodiments, the bit line liner is a conformal layer. In some embodiments, the bit line liner is deposited by atomic layer deposition.

In some embodiments, the bit line material 254 comprises a bit line metal. The bit line metal may comprise any suitable metal known to the skilled artisan. In one or more embodiments, the bit line metal comprises or consists essentially of one or more of tungsten silicide (WSi), tungsten nitride (WN), or tungsten (W). The bit line metal can be deposited by any suitable technique known to the skilled artisan and can be any suitable material. In one or more embodiments, forming the bit line material 254 further comprises forming a bit line metal seed layer (not shown) prior to depositing the bit line metal.

Referring to FIG. 3R, in one or more embodiments, an insulator layer 256 is deposited to fill the bit line trench 236 adjacent to the bit line material 252. The insulator layer 256 may comprise any suitable material known to the skilled artisan. In some embodiments, the insulator layer 256 comprises silicon oxide (SiOₓ).

As illustrated in FIG. 3S, the sacrificial material 234 is removed from a portion of the device 200 to form a capacitor trench 258 on a side of the device 200 opposite the bit line 254. The sacrificial material 234 may be removed using any suitable removal process known to the skilled artisan.

With reference to FIG. 3T, the plurality of channel layers 204 are recessed through the capacitor trench 258 to form a recess opening 260 between the oxide material 230 and adjacent to the plurality of channel layers 204. The plurality of channel layers 204 forms a sidewall surface of the recess opening 260.

Referring to FIG. 3U, in one or more embodiments, the oxide material 230 layers are thinned or trimmed to decrease the thickness of the oxide material 230 layers and increase the height of the recess opening 260 to form an enlarged recess opening 262. The oxide material 230 layers may be trimmed according to any suitable process known to the skilled artisan.

As illustrated in FIG. 3V, in one or more embodiments, the source/drain of the capacitor is formed by deposition of a source/drain material 264 on the plurality of channel layers 204 on an end opposite from the source/drain material 252 of the bit line. The source/drain material 264 is formed on the exposed sidewall surface of the plurality of channel layers 204. The source/drain material 264 may comprise any suitable material known to the skilled artisan. In some embodiments, the source/drain material 264 may have more than one layer. In some embodiments, the source/drain material 264 comprises a layer of silicon with doped epi (e.g., Si, SiGe, and the like doped with one or more dopant), a second layer of silicide, which may contain nickel (Ni), titanium (Ti), aluminum (Al), and the like, and a third, or top, layer which may be a metal such as, but not limited to, cobalt, tungsten, ruthenium, aluminum, and the like.

With reference to FIG. 3W, in one or more embodiments, the capacitor bottom electrode 266 is deposited on the device 200 and on the source/drain material 264. The capacitor bottom electrode 266 may comprise any suitable material known to the skilled artisan. In one or more embodiments, the capacitor bottom electrode 266 comprises or consists essentially of one or more of tungsten silicide (WSi), tungsten nitride (WN), or tungsten (W). The capacitor bottom electrode 266 can be deposited by any suitable technique known to the skilled artisan and can be any suitable material.

Referring to FIG. 3X, in one or more embodiments, an oxide material 270 is deposited to fill the opening 268 between the oxide material 230 layers having the bottom electrode 266 thereon. The oxide material 270 may comprise any suitable material known to the skilled artisan. In one or more embodiments, the oxide material 270 comprises silicon oxide (SiOₓ).

As illustrated in FIG. 3Y, the bottom electrode node is then separated by removing the bottom electrode 266 from the sidewall 272 of the oxide material 230 layers. The bottom electrode 266 may be removed by any suitable process known to the skilled artisan.

With reference to FIG. 3Z, in one or more embodiments, the bottom electrode 266 is then exposed by removing the oxide material 230 layers and the oxide material 270. The oxide material 230 layers and the oxide material 270 may be removed by any suitable process known to the skilled artisan.

Referring to FIG. 3AA, a capacitor dielectric layer 278 is formed on the exposed on the bottom electrode 266. In one or more embodiments, the capacitor dielectric layer 278 may comprise any suitable material. In some embodiments, the capacitor dielectric layer 278 comprises a high-κ dielectric material. In some embodiments, high-κ dielectric material comprises a metal selected from one or more of hafnium, zirconium, silicon, lanthanum, aluminum, titanium, and strontium. This may produce an oxide layer as the capacitor dielectric layer 278 by atomic layer deposition.

As illustrated in FIG. 3BB, a top electrode 280 is then deposited in the capacitor trench 258 on the capacitor dielectric layer 278 to fill the trench 258. The top electrode 280 may be deposited by any suitable deposition process known to the skilled artisan. The top electrode 280 may comprise any suitable material known to the skilled artisan. In one or more embodiments, the top electrode 280 comprises or consists essentially of one or more of tungsten silicide (WSi), tungsten nitride (WN), or tungsten (W).

With reference to FIG. 3CC, the bonding pads 282 are then formed on the capacitor side and bit line side of the device.

Referring to FIG. 3DD, in one or more embodiments, the device 200 is rotated or flipped 180 degrees. The array wafer 285 is bonded to a peri wafer 287. The array wafer 285 may be bonded by any suitable process known to the skilled artisan. In one or more embodiments, the peri wafer 287 includes peripheral transistors (address decoders, sense amps, and muxes) to manage the 3D memory array.

As illustrated in FIG. 3EE, the backside silicon is thinned and the remaining silicon layer 299 is removed to form an opening 290 exposing the etch stop material 222. The silicon layer 299 may be removed using any suitable process known to the skilled artisan. For example, the silicon layer 299 may be removed by a wet etch process.

With reference to FIG. 3FF, in one or more embodiments, the opening 292 is filled with an oxide material 292. The oxide material 292 may comprise any suitable oxide material known to the skilled artisan. In some embodiments, the oxide material 292 comprises silicon oxide (SiOₓ). The oxide material 292 may be formed by any suitable deposition technique known to the skilled artisan, such as, but not limited to, ALD, CVD, PVD, MBE, MOCVD, spin-on, or other deposition techniques known to the skilled artisan. In some embodiments, the oxide material 292 is deposited on the etch stop material 222 by CVD.

Referring to FIG. 3GG, in one or more embodiments, the device 200 is planarized, e.g., by chemical mechanical planarization (CMP) and the etch stop material 222 prevents over thinning of the device 200.

As illustrated in FIG. 3HH, metallization 296 of the device 200 occurs according to standard processing.

In one or more embodiments, metal deposition and other processes can be carried out in an isolated environment (e.g., a cluster process tool). Accordingly, some embodiments of the disclosure provide integrated tool systems with related process modules to implement the methods.

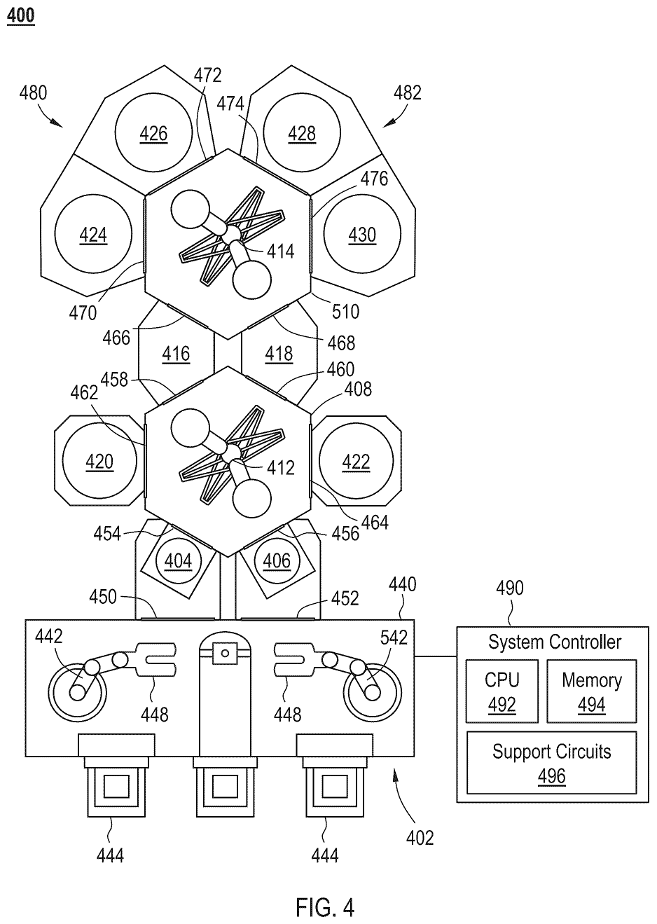

One or more embodiments of the disclosure are directed to integrated processes which are performed within a single cluster tool. FIG. 4 illustrates a schematic top-view diagram of an example of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, and 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 400. Accordingly, the processing system 400 may provide an integrated solution for some processing of wafers.

In the illustrated example of FIG. 4, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 442 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In one or more embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A memory device comprising:
a memory stack on an etch stop layer on a substrate, the memory stack comprising a plurality of channel layers and a corresponding plurality of sacrificial layers alternatingly arranged in a plurality of stack pairs, the etch stop layer having an etch stop layer thickness and each of the plurality of sacrificial layers having a sacrificial layer thickness, the etch stop layer thickness greater than the sacrificial layer thickness.

2. The memory device of claim 1, wherein the etch stop layer thickness is in a range of from greater than 10 nm to 100 nm.

3. The memory device of claim 1, wherein the etch stop layer comprises silicon nitride (SiN).

4. The memory device of claim 1, wherein the sacrificial layer thickness is in a range of from 5 nm to 70 nm.

5. The memory device of claim 1, wherein the plurality of channel layers comprise silicon.

6. The memory device of claim 1, further comprising a second substrate having peripheral transistors, the second substrate bonded to an opposing end of the memory device from the substrate.

7. A memory array comprising the memory device of claim 1 on a peri wafer.

8. A method of manufacturing a DRAM device, the method comprising:
forming a memory stack on a sacrificial etch stop layer on a substrate, the memory stack comprising a plurality of channel layers and a corresponding plurality of sacrificial layers alternatingly arranged in a plurality of stacked pairs, the sacrificial etch stop layer having a first thickness and each of the plurality of sacrificial layers having a second thickness, the first thickness greater than the second thickness;
replacing the sacrificial etch stop layer with an etch stop layer; and
replacing each of the plurality of sacrificial layers with an oxide material.

9. The method of claim 8, wherein the first thickness is in a range of from greater than 10 nm to 100 nm.

10. The method of claim 8, wherein the etch stop layer comprises silicon nitride (SiN).

11. The method of claim 8, wherein the second thickness is in a range of from 5 nm to 70 nm.

12. The method of claim 8, wherein the plurality of channel layers comprise epitaxial silicon.

13. The method of claim 8, wherein the sacrificial etch stop layer and the plurality of sacrificial layers comprises silicon germanium (SiGe).

14. The method of claim 13, wherein the silicon germanium (SiGe) is doped with a dopant comprising carbon.

15. The method of claim 14, wherein the silicon germanium (SiGe) comprises in a range of from 0 atomic % germanium (Ge) to 30 atomic % germanium (Ge) and in a range of from 0 atomic % carbon to 1 atomic % carbon.

16. The method of claim 14, wherein the silicon germanium (SiGe) comprises in a range of from 0 atomic % germanium (Ge) to 10 atomic % germanium (Ge) and in a range of from 0 atomic % carbon to 1 atomic % carbon.

17. The method of claim 13, wherein the sacrificial etch stop layer has a concentration of germanium that is less than the concentration of germanium in the plurality of sacrificial layers.

18. The method of claim 8, further comprising forming a memory hole in the memory stack, the memory hole extending from a top surface of the memory stack to the substrate, the memory hole having a critical dimension (CD).

19. The method of claim 18, wherein the first thickness greater is about half the critical dimension.

20. The method of claim 8, further comprising:
performing processing of the memory stack to form a first semiconductor structure that comprises a 3D memory array;
hybrid bonding the first semiconductor structure to a second semiconductor structure, wherein the second semiconductor structure comprises a second substrate and peripheral transistors to manage the 3D memory array, the peripheral transistors comprising one or more of address decoders, sense amps, and muxes; and
after the bonding, etching the first semiconductor structure while using the etch stop layer to stop the etching process.
